(19) United States
(12) Patent Application Publication
(10) Pub. No.: US 2026/0248003 A1
(43) Pub. Date: Aug. 20, 2026

(54) SUBSTRATE STRUCTURE

(71) Applicant: SILICONWARE PRECISION INDUSTRIES CO., LTD., Taichung City (TW)

(72) Inventors: Ching-Chih LIN, Taichung City (TW); Wen-Chen HSIEH, Taichung City (TW); Chia-Wen TSAO, Taichung City (TW); Hsiu-Fang CHIEN, Taichung City (TW)

(21) Appl. No.: 19/175,735

(22) Filed: Apr. 10, 2025

(30) Foreign Application Priority Data
Feb. 20, 2025 (TW) 114106306

(51) Int. Cl. H10W 70/65; H10W 70/685

(52) U.S. Cl. CPC H10W 70/65; H10W 70/685

(57) ABSTRACT

A substrate structure is provided and includes a substrate body, a patterned metal layer, and an insulating protective layer. The substrate body has a circuit layer and is defined with a chip placement region, and the patterned metal layer is formed on the substrate body. The insulating protective layer has an opening corresponding to the chip placement region and exposing a part of the circuit layer and a part of the patterned metal layer, so as to mitigate the problem of delamination by reducing the area of the patterned metal layer exposed from the opening of the insulating protective layer.

### CROSS-REFERENCE TO RELATED APPLICATIONS

The present application is based upon and claims the right of priority to TW Patent Application No. 114106306, filed on February 20, 2025, the disclosure of which is hereby incorporated by reference herein in its entirety for all purposes.

### BACKGROUND

### 1. Technical Field

The present disclosure relates to a semiconductor structure, and more particularly, to a substrate structure for carrying an electronic element.

### 2. Description of Related Art

With the development of the electronics industry, electronic products have been designed to be thin, light, short and with diversified functions, and semiconductor packaging technology has also developed different packaging types. In order to meet the requirements of high integration and miniaturization of semiconductor devices, the industry generally uses a flip-chip package structure.

FIGS. 1A and FIG. 1B are respectively a cross-sectional schematic diagram and a partial top schematic diagram of a conventional flip-chip package 1. As shown in FIG. 1A, a package substrate 10 has a circuit layer 100 (which is composed of, for example, copper wires), an insulating protective layer 101, and an opening 102 exposing the circuit layer 100, wherein the package substrate 10 is defined with a chip placement region D. A semiconductor chip 11 is bonded to the circuit layer 100 in the chip placement region D of the package substrate 10 via a plurality of solder bumps 12, and then an underfill 13 is formed between the semiconductor chip 11 and the package substrate 10 to encapsulate the plurality of solder bumps 12, wherein the circuit layer 100 includes electrical contacts (solder pads) electrically connected to the semiconductor chip and a large-area metal layer (copper layer) providing power/grounding functions.

However, the bonding strength between the underfill 13 and the circuit layer 100 in the chip placement region D is poor due to the large-area contact, which is prone to delamination problems, so that the underfill 13 and the package substrate 10 are prone to separation.

Therefore, there is a need for a solution that addresses the aforementioned shortcomings in the prior art.

### SUMMARY

In view of the aforementioned shortcomings of the prior art, the present disclosure provides a substrate structure, which comprises: a substrate body arranging with a circuit layer on a surface thereof and defined with a chip placement region on the surface; a patterned metal layer formed on the surface; and an insulating protective layer formed on the surface and having an opening corresponding to the chip placement region and exposing a part of the circuit layer and a part of the patterned metal layer, wherein an area of the circuit layer and the patterned metal layer exposed from the opening accounts for 45% to 55% of an area of the opening.

In the aforementioned substrate structure, the substrate body is a substrate with a core layer or a substrate without a core layer.

In the aforementioned substrate structure, the circuit layer includes a plurality of electrical contact pads and a plurality of conductive traces connected to the plurality of electrical contact pads.

In the aforementioned substrate structure, the patterned metal layer is used to provide power or ground.

In the aforementioned substrate structure, the patterned metal layer includes a plurality of metal blocks and a plurality of metal wires connected to at least two of the plurality of metal blocks.

In the aforementioned substrate structure, the patterned metal layer includes a large-area metal layer and a plurality of grooves formed in the large-area metal layer, and the substrate body is exposed from the plurality of grooves. Shapes of the plurality of grooves are square, circular, oval, or irregular.

In the aforementioned substrate structure, the patterned metal layer includes grid-type metal lines. In addition, the patterned metal layer further includes metal blocks connected to the grid-type metal lines.

In the aforementioned substrate structure, the insulating protective layer is formed with a plurality of insulating blocks in the chip placement region located in the opening. In addition, the plurality of insulating blocks are spaced apart from each other, and shapes of the plurality of insulating blocks are circular, square, or irregular.

As can be understood from the above, in the substrate structure according to the present disclosure, the area of the patterned metal layer (for example, the patterned metal layer presented in the form of fine metal wires, grooves, grids, or multiple insulating blocks formed in the opening) exposed from the opening of the insulating protective layer in the chip placement region on the surface of the substrate body is reduced, allowing the area of the circuit layer and the patterned metal layer exposed from the opening to account for approximately 45% to 55% of the area of the opening, thereby effectively reducing the ratio of exposed copper (the circuit layer and the patterned metal layer), reducing the contact area between the underfill and the copper, and mitigating the delamination problem.

### BRIEF DESCRIPTION OF THE DRAWINGS

FIGS. 1A and FIG. 1B are respectively a cross-sectional schematic diagram and a partial top schematic diagram of a conventional flip-chip package structure.

FIGS. 2A to FIG. 2C are schematic top views of a first embodiment of a substrate structure of the present disclosure.

FIG. 3 is a schematic top view of a second embodiment of a substrate structure of the present disclosure.

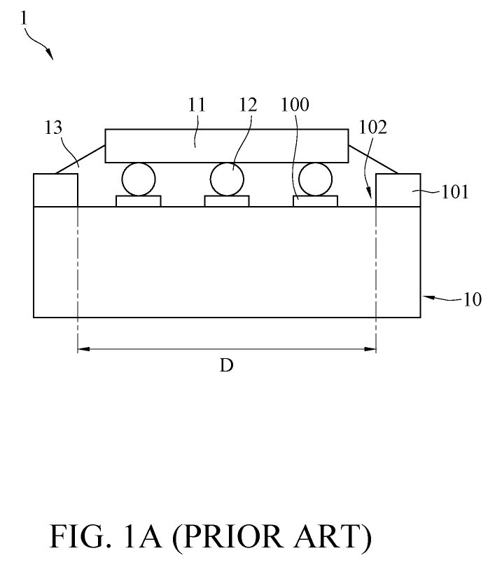

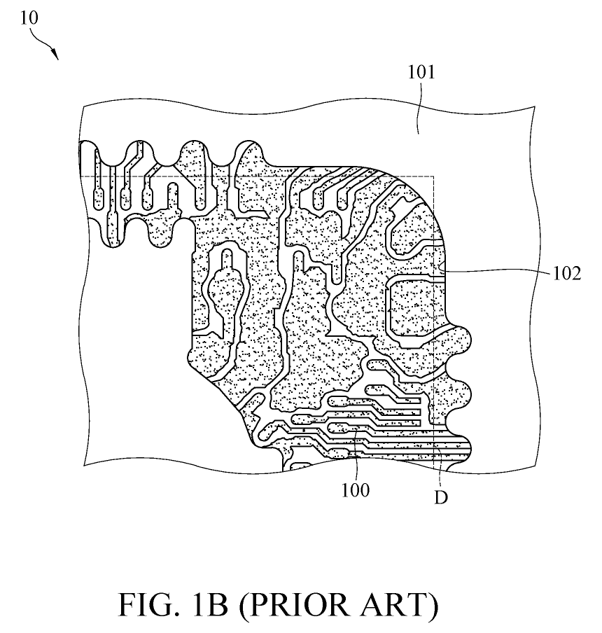

### DETAILED DESCRIPTION

Embodiments of the present disclosure are described below by examples. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes, or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

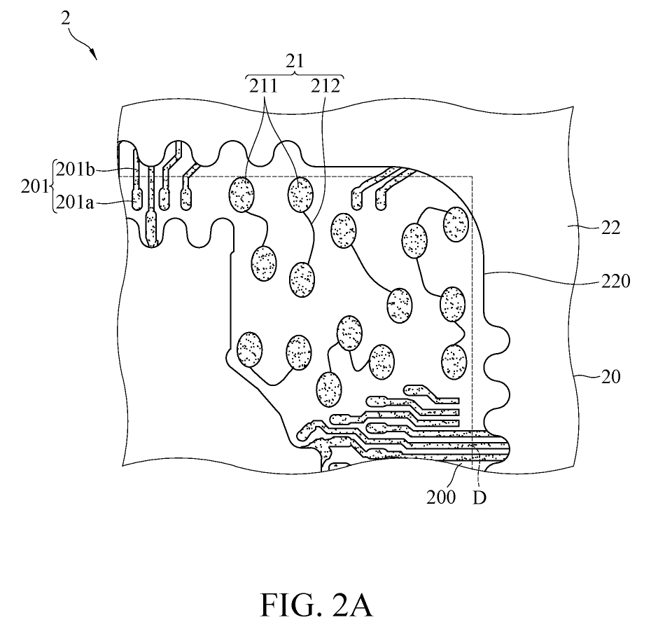

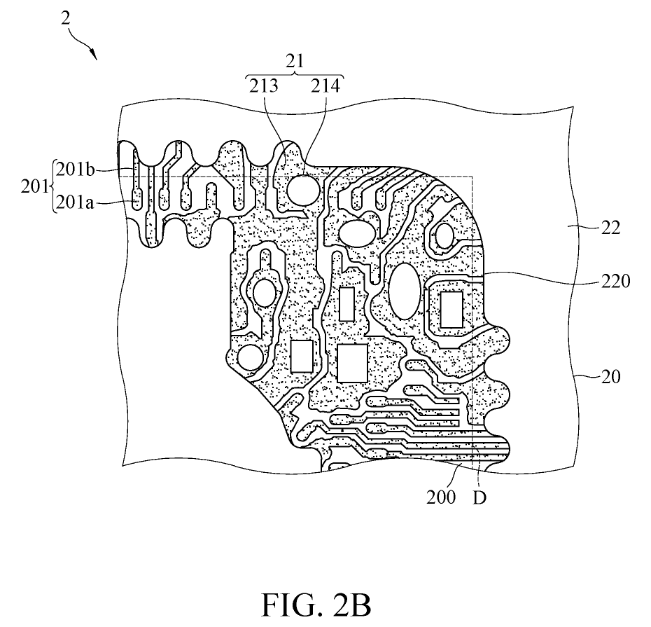

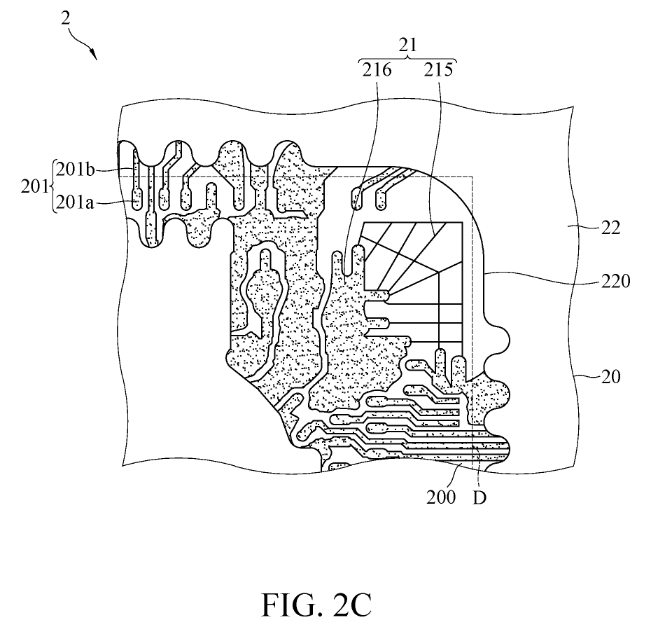

FIGS. 2A to FIG. 2C are schematic top views of a first embodiment of a substrate structure 2 of the present disclosure.

The substrate structure 2 of the present disclosure is, for example, a package substrate for carrying a semiconductor chip, and the substrate structure 2 comprises a substrate body 20, a patterned metal layer 21, and an insulating protective layer 22.

The substrate body 20 is, for example, a substrate with a core layer or a substrate without a core layer (a coreless substrate). A circuit layer 201 is disposed on a surface 200 of the substrate body 20, and a chip placement region D is defined on the surface 200.

In one embodiment, the substrate body 20 includes at least one insulating layer and at least one routing layer (not shown) formed on the insulating layer. The routing layer may be, for example, a fan-out redistribution layer (RDL), and the outermost routing layer is served as the circuit layer 201. The circuit layer 201 includes a plurality of electrical contact pads 201a and a plurality of conductive traces 201b connected to the plurality of electrical contact pads 201a. The chip placement region D is used for an electronic element such as a semiconductor chip or a passive element to be disposed thereon. For example, the electronic element is connected to the electrical contact pads 201a via conductive bumps to form an electronic package.

Furthermore, the routing layer is made of copper, and the insulating layer is made of polybenzoxazole (PBO), polyimide (PI), prepreg (PP), or other dielectric materials.

The patterned metal layer 21 is disposed on the surface 200 of the substrate body 20 and is adjacent to the circuit layer 201, wherein the patterned metal layer 21 is designed to provide power/grounding.

In one embodiment, as shown in FIG. 2A, the patterned metal layer 21 includes a plurality of metal blocks 211 and a plurality of metal wires (fine circuits) 212 connected to at least two of the plurality of metal blocks 211.

In another embodiment, as shown in FIG. 2B, the patterned metal layer 21 includes a large-area metal layer 213 and a plurality of grooves 214 formed in the large-area metal layer 213, so that the substrate body 20 is exposed from the plurality of grooves 214. The shapes of the grooves 214, as shown in the figure, may be square, circular, or oval, and they may also be designed into other suitable shapes, such as irregular ones, depending on actual conditions.

In yet another embodiment, as shown in FIG. 2C, the patterned metal layer 21 includes grid-type metal lines 215. In addition, the patterned metal layer 21 further includes metal blocks 216 connected to the grid-type metal lines 215.

The insulating protective layer 22 is formed on the surface 200 of the substrate body 20 and has at least one opening 220. In one embodiment, the opening 220 corresponds to the chip placement region D and exposes a part of the circuit layer 201 and a part of the patterned metal layer 21. A part of the opening 220 is located in the chip placement region D, and the remaining part of the opening 220 is located outside the chip placement region D. The opening 220 outside the chip placement region D allows the underfill to effectively flow between the electronic element and the substrate body 20. Furthermore, the insulating protective layer 22 can be made of solder mask (e.g., green solder mask), ink (e.g., solder resist ink), or other solder resist materials.

In the substrate structure 2 of this embodiment, the area of the patterned metal layer 21 exposed from the opening 220 (full-open window type) of the insulating protective layer 22 is reduced, so that the area of the circuit layer 201 and the patterned metal layer 21 exposed from the opening 220 (metal material area) occupies approximately 45% to 55% of the area of the opening 220, so as to solve the problem that when a large area of metal layer (copper layer) is exposed from the conventional substrate structure through a full-open window, the larger the exposed copper area, the worse the bonding between the underfill and the copper.

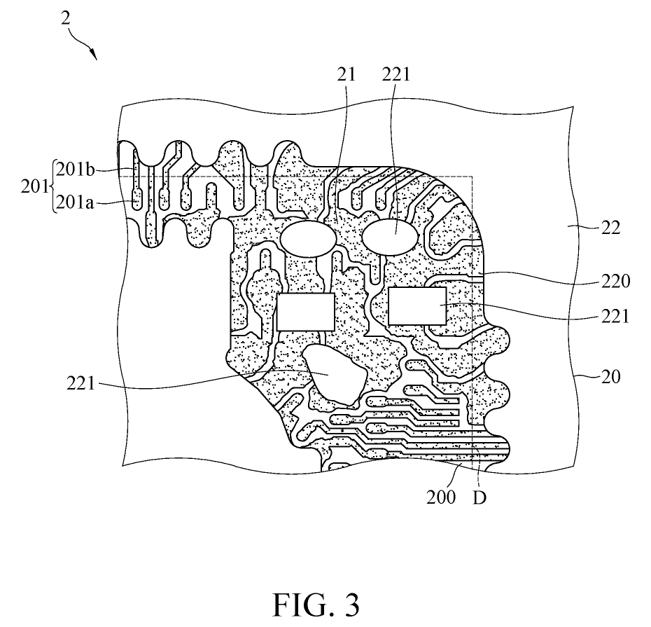

FIG. 3 is a schematic top view of a second embodiment of a substrate structure 2 of the present disclosure.

The substrate structure 2 of this embodiment is substantially the same as the aforementioned embodiment, including a substrate body 20, a patterned metal layer 21, and an insulating protective layer 22. The main difference is that the insulating protective layer 22 is further formed with a plurality of insulating blocks 221 located in a chip placement region D within an opening 220.

The plurality of insulating blocks 221 cover a part of the patterned metal layer 21 to reduce the area of the patterned metal layer 21 exposed from the opening 220. Furthermore, the plurality of insulating blocks 221 are spaced apart from each other, and the shapes of the insulating blocks 221 may be circular, square, or irregular, but the present disclosure is not limited to as such.

In view of the above, in the substrate structure according to the present disclosure, the area of the patterned metal layer (for example, the patterned metal layer presented in the form of fine metal wires, grooves, grids, or multiple insulating blocks formed in the opening) exposed from the opening of the insulating protective layer in the chip placement region on the surface of the substrate body is reduced, allowing the area of the circuit layer and the patterned metal layer exposed from the opening to account for approximately 45% to 55% of the area of the opening, thereby effectively reducing the ratio of exposed copper (the circuit layer and the patterned metal layer), reducing the contact area between the underfill and the copper, and mitigating the delamination problem.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A substrate structure, comprising:
a substrate body arranging with a circuit layer on a surface thereof and defined with a chip placement region on the surface;
a patterned metal layer formed on the surface; and
an insulating protective layer formed on the surface and having an opening corresponding to the chip placement region and exposing a part of the circuit layer and a part of the patterned metal layer, wherein an area of the circuit layer and the patterned metal layer exposed from the opening accounts for 45% to 55% of an area of the opening.

2. The substrate structure of claim 1, wherein the substrate body is a substrate with a core layer or a substrate without a core layer.

3. The substrate structure of claim 1, wherein the circuit layer includes a plurality of electrical contact pads and a plurality of conductive traces connected to the plurality of electrical contact pads.

4. The substrate structure of claim 1, wherein the patterned metal layer is for power or ground use.

5. The substrate structure of claim 1, wherein the patterned metal layer includes a plurality of metal blocks and a plurality of metal wires connected to at least two of the plurality of metal blocks.

6. The substrate structure of claim 1, wherein the patterned metal layer includes a large-area metal layer and a plurality of grooves formed in the large-area metal layer, and the substrate body is exposed from the plurality of grooves.

7. The substrate structure of claim 6, wherein shapes of the plurality of grooves are square, circular, oval, or irregular.

8. The substrate structure of claim 1, wherein the patterned metal layer includes grid-type metal lines.

9. The substrate structure of claim 8, wherein the patterned metal layer further includes metal blocks connected to the grid-type metal lines.

10. The substrate structure of claim 1, wherein the insulating protective layer is formed with a plurality of insulating blocks in the chip placement region located in the opening.

11. The substrate structure of claim 10, wherein the plurality of insulating blocks are spaced apart from each other, and shapes of the plurality of insulating blocks are circular, square, or irregular.
